(19) United States
(12) Patent Application Publication
(10) Pub. No.: US 2010/0036144 A1
(43) Pub. Date: Feb. 11, 2010

(54) METHODS FOR ATOMIC LAYER DEPOSITION

(76) Inventors: Ce Ma, San Diego, CA (US); Graham McFarlane, Carlsbad, CA (US); Qing Min Wang, North Andover, MA (US); Patrick J. Helly, Valley Center, CA (US)

Correspondence Address: The BOC Group, Inc., 575 MOUNTAIN AVENUE, MURRAY HILL, NJ, 07974-2082, US

(21) Appl. No.: 12/373,913

(22) PCT Filed: Jul. 12, 2007
(86) PCT No.: PCT/US07/15917

§ 371 Date: Jul. 29, 2009

Related U.S. Application Data
(60) Provisional application No. 60/832,209, filed on Jul. 20, 2006.

(51) Int. Cl. C23C 16/44; C07F 7/28; C07F 7/00; C07F 5/06; C07F 7/24; C07F 15/00

(52) U.S. Cl. 556/27; 427/255.23; 556/51; 556/56; 556/81; 556/136

(57) ABSTRACT

Improved methods for performing atomic layer deposition (ALD) are described. These improved methods provide more complete saturation of the surface reactive sites and provides more complete monolayer surface coverage at each half-cycle of the ALD process. In one embodiment, operating parameters are fixed for a given solvent based precursor. In another embodiment, one operating parameter, e.g. chamber pressure is altered during the precursor deposition to assure full surface saturation.

### CROSS REFERENCE TO RELATED APPLICATIONS

This application claims priority from international Application Serial No. PCT/US2007/015917, filed 12 Jul. 2007 (published as WO 2008/010941 A2, with publication date 24 Jan. 2008), which claims priority from U.S. Application No. 60/832,209 filed 20 Jul. 2006.

### FIELD OF THE INVENTION

The present invention relates to new and useful methods for atomic layer deposition.

### BACKGROUND OF THE INVENTION

Atomic layer deposition (ALD) is an enabling technology for next generation conductor barrier layers, high-k gate dielectric layers, high-k capacitance layers, capping layers, and metallic gate electrodes in silicon wafer processes. ALD has also been applied in other electronics industries, such as flat panel display, compound semiconductor, magnetic and optical storage, solar cell, nanotechnology and nano materials. ALD is used to build ultra thin and highly conformal layers of metal, oxide, nitride, and others one monolayer at a time in a cyclic deposition process. Oxides and nitrides of many main group metal elements and transition metal elements, such as aluminum, titanium, zirconium, hafnium, and tantalum, have been produced by ALD processes using oxidation or nitridation reactions. Pure metallic layers, such as Ru, Cu, Ta, and others may also be deposited using ALD processes through reduction or combustion reactions.

A typical ALD process is based on sequential applications of at least two precursors to the substrate surface with each pulse of precursor separated by a purge. Each application of a precursor is intended to result in a single monolayer of material being deposited on the surface. These monolayers are formed because of the self-terminating surface reactions between the precursors and surface. In other words, reaction between the precursor and the surface should proceed until no further surface sites are available for reaction. Excess precursor is then purged from the deposition chamber and the second precursor is introduced. Each precursor pulse and purge sequence comprises one ALD half-cycle that theoretically results in a single additional monolayer of material. Because of the self-terminating nature of the process, even if more precursor molecules arrive at the surface, no further reactions will occur. It is this self-terminating characteristic that provides for high uniformity, conformality and precise thickness control when using ALD processes.

However, in practice, it has been found that ALD processes are often limited to film growth rates of half a monolayer or less. In particular, film growth rates can be influenced by the choice of precursor and by temperature and pressure limits for the selected precursor. In addition, steric hindrances from the size and shape of precursor ligands can limit the film growth rate given because of the fixed surface density of active reaction sites. These less than complete growth rates for ALD operations present production problems in wafer throughput and cost of manufacturing. In addition, sub-monolayer growth can result in island type growth and thus higher surface roughness.

There remains a need in the art for improvements to ALD processes.

### SUMMARY OF THE INVENTION

The present invention provides an ALD process that allows for thin film growth rate to be tuned to the needs of a particular deposition process by precursor composition (metal precursor concentration and solvent selection) or manipulation of process conditions (pressure, temperature).

In addition, the present invention provides an ALD process that allows for thin film growth rate to be tuned during the deposition by manipulation of process conditions (e.g. pressure).

### BRIEF DESCRIPTION OF THE DRAWINGS

FIG. 1 is a graph plotting ALD growth rate of HfO₂ under different deposition temperature, deposition pressure and pulse length conditions.

FIG. 2 is a graph plotting ALD growth rate of HfO₂ under different pressure conditions, while holding precursor concentration, delivery flow rate and deposition temperature constant.

### DETAILED DESCRIPTION OF THE INVENTION

The present invention relies on solvent based precursors. Suitable solvent based precursors are disclosed in applicants co-pending U.S. patent application Ser. No. 11/400,904, filed Apr. 10, 2006. Examples of precursor solutes that can be selected from a wide range of low vapor pressure solutes or solids as set forth in Table 1.

TABLE 1
Examples of ALD precursor solutes

| | | | | bp (° C./ | |
|---|---|---|---|---|---|
| Name | Formula | MW | Mp (° C.) | mmHg) | Density (g/mL) |
| Tetrakis(ethylmethylamino) | Hf[N(EtMe)]₄ | 410.9 | −50 | 79/0.1 | 1.324 |
| hafnium (TEMAH) | | | | | |
| Hafnuim (IV) Nitrate, | Hf(NO₃)₄ | 426.51 | >300 | n/a | |
| anhydrous | | | | | |
| Hafnuim (IV) Iodide, | HfI₄ | 686.11 | 400 | n/a | 5.6 |
| anhydrous | | | (subl.) | | |
| Dimethylbis(t-butyl | [(t-Bu)Cp]₂HfMe₂ | 450.96 | 73-76 | n/a | |
| cyclopentadienyl hafnium(IV) | | | | | |
| Tetrakis(1-methoxy-2-methyl- | Hf(O₂C₅H₁₁)4 | 591 | n/a | 135/0.01 | |
| 2-propoxide) hafnium (IV) | | | | | |
| Di(cyclopentadienyl)Hf | Cp₂HfCl₂ | 379.58 | 230-233 | n/a | |
| dichloride | | | | | |
| Hafnium tert-butoxide | Hf(OC₄H₉)₄ | 470.94 | n/a | 90/5 | |
| Hafnium ethoxide | Hf(OC₂H₅)₄ | 358.73 | 178-180 | 180-200/13 | |
| Aluminum i-propoxide | Al(OC₃H₇)₃ | 204.25 | 118.5 | 140.5/8 | 1.0346 |
| Lead t-butoxide | Pb(OC(CH₃)₃)₂ | 353.43 | | | |
| Zirconium (IV) t-butoxide | Zr(OC(CH₃)₃)₄ | 383.68 | | 90/5; 81/3 | 0.985 |
| Titanium (IV) i-propoxide | Ti(OCH(CH₃)₂)₄ | 284.25 | 20 | 58/1 | 0.955 |
| Barium t-propoxide | Ba(OC₃H₇)₂ | 255.52 | 200 (dec) | n/a | |
| Strontium i-propoxide | Sr(OC₃H₇)₂ | 205.8 | | | |
| Bis(pentamethylCp) Barium | Ba(C₅Me₅)₂ | 409.8 | | | |
| Bis(tripropylCp) Strontium | Sr(C₅i-Pr₃H₂)₂ | 472.3 | | | |
| (Trimethyl)pentamethylcyclo- | Ti(C₅Me₅)(Me₃) | 228.22 | | | |
| pentadienyl titanium (IV) | | | | | |
| Bis(2,2,6,6-tetramethyl-3,5- | Ba(thd)₂ * | 503.85 | 88 | | |
| heptanedionato) barium | triglyme | (682.08) | | | |
| triglyme adduct | | | | | |
| Bis(2,2,6,6-tetramethyl-3,5- | Sr(thd)₂ * | 454.16 | 75 | | |
| heptanedionato) strontium | triglyme | (632.39) | | | |
| triglyme adduct | | | | | |
| Tris(2,2,6,6-tetramethyl-3,5- | Ti(thd)₃ | 597.7 | | 75/0.1 (sp) | |
| heptanedionato) titanium(III) | | | | | |
| Bis(cyclpentadinyl)Ruthenium | RuCp₂ | 231.26 | 200 | 80-85/0.01 | |
| (II) | | | | | |

Other examples of precursor solutes include Ta(NMe₂)₅ and Ta(NMe₂)₃(NC₉H₁₁) that can be used as Tantalum film precursors.

The selection of solvents is critical to the ALD precursor solutions. In particular, examples of solvents useful with the solutes noted above are given in Table 2.

TABLE 2
Examples of solvents

| Name | Formula | BP@760 Torr (° C.) |
|---|---|---|
| Dioxane | C₄H₈O₂ | 101 |
| Toluene | C₇H₈ | 110.6 |
| n-butyl acetate | CH₃CO₂(n-Bu) | 124-126 |
| Octane | C₈H₁₈ | 125-127 |
| Ethylcyclohexane | C₈H₁₆ | 132 |
| 2-Methoxyethyl acetate | CH₃CO₂(CH₂)₂OCH₃ | 145 |
| Cyclohexanone | C₆H₁₀O | 155 |
| Propylcyclohexane | C₉H₁₈ | 156 |
| 2-Methoxyethyl Ether | (CH₃OCH₂CH₂)₂O | 162 |
| (diglyme) | | |
| Butyl cyclohexane | C₁₀H₂₀ | 178 |

Another example of a solvent useful for the present invention is 2,5-dimethyloxytetrahydrofuran.

The present invention is directed to methods of using solvent based precursors, such as those noted above in order to obtain a fixed ALD thin film growth rate. The method of the present invention is described as follows.
1. Select a metal precursor and solvent combination.
2. Dissolve the metal precursor in the solvent to a selected concentration.
3. Deliver the precursor solution to a vaporizer at a fixed flow rate.
4. Deliver the vaporized solution to a deposition chamber at a fixed temperature and pressure for a fixed length of time.
5. Purge the deposition chamber with inert gas for a fixed length of time.
6. Deliver a second precursor (such as a reactive species, e.g. oxidizer) to the deposition chamber for a fixed length of time.
7. Purge the deposition chamber with inert gas for a fixed length of time.
8. Repeat 3 through 7 above until the desired thin film thickness is achieved.

In accordance with the present invention, specific film growth rates can be achieved by establishing particular operation parameters for the precursor/solvent combination. For example, Table 3 shows parameters that can be varied depending on the precursor/solvent combination, as long as they are kept within ranges where ALD growth occurs.

TABLE 3

| Parameter | Range |
|---|---|
| Metal precursor | Solid or liquid |
| Solvent | Non reacting solvent |
| Metal precursor concentration | 0.01-10 Molar |
| Flow Rate of the precursor solution | 0.01-10000 uL/min liquid |
| Deposition temperature | 100-600 C. |
| Deposition Pressure | 0.1-10 Torr |

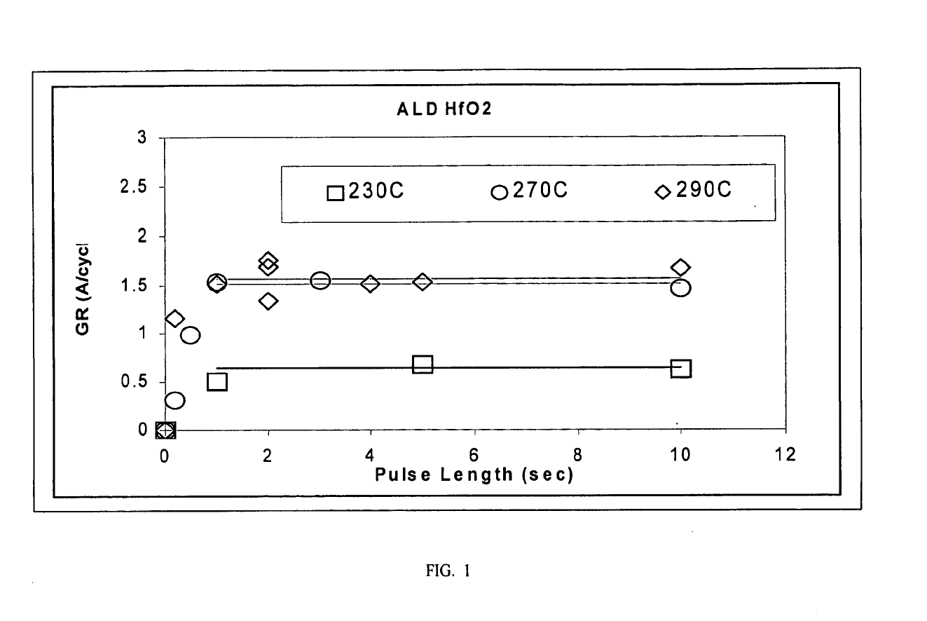

FIG. 1 shows some experimental results in accordance with the present invention. In particular, FIG. 1 shows ALD film growth rates for a HfO2 thin film using a solvent-based precursor. The precursor solution consisted of 0.2M ((t-Bu)Cp)₂HfMe₂ in n-Octane and was delivered to a vaporizer at a flow rate of 1-4 ul/min. Three different deposition conditions were tried, i.e. deposition temperature 230° C. and deposition pressure 0.8 Torr; deposition temperature 270° C. and deposition pressure 7 Torr; deposition temperature 290° C. and deposition pressure 4 Torr. Results of these experiments are shown in Table 4.

TABLE 4

| Deposition Temperature | Deposition Pressure | Thin Film Growth Rate |
|---|---|---|
| (° C.) | (Torr) | (A/cycle) |
| 230 | 0.8 | 0.7 |
| 270 | 7 | 1.5 |
| 290 | 4 | 1.6 |

It can be seen from FIG. 1 that substrate saturation is reached at a metal precursor pulse width of about 1 s. Further increases in metal precursor pulse width did not alter the growth rates, thus establishing that this was true ALD behavior. Further, this experiment showed that different self-limiting growth rates can be achieved by using different combinations of temperature and pressure. In comparison, ALD growth rates using conventional methods and conventional precursors are always less than one monolayer per cycle. Therefore, the present invention provides a method of obtaining higher ALD growth rates that those that can be achieved by conventional ALD methods. This advantage may at least in part be caused by the solvent assisting the substrate absorption of the metal precursor molecules and helping to remove precursor ligands from the substrate surface.

The present invention also provides a method of performing variable growth rates of an ALD film by adjusting one or more operation parameters; e,g, temperature or pressure during deposition. It is preferred according to the present invention to change deposition pressure during an ALD deposition process. In one example, the growth rate of ALD thin films can be altered during deposition by the following method.
1. Select a metal precursor and solvent combination.
2. Dissolve the metal precursor in the solvent to a selected concentration.
3. Deliver the precursor solution to a vaporizer at a fixed flow rate.
4. Deliver the vaporized solution to a deposition chamber at a fixed temperature for a fixed length of time.
5. Alter the pressure (increase or decrease) of the deposition chamber to change the thin film growth rate.
6. Purge the deposition chamber with inert gas for a fixed length of time.
7. Deliver a second precursor (such as a reactive species, e.g. oxidizer) to the deposition chamber for a fixed length of time.
8. Purge the deposition chamber with inert gas for a fixed length of time.
9. Repeat 3 through 7 above until the desired thin film thickness is achieved.

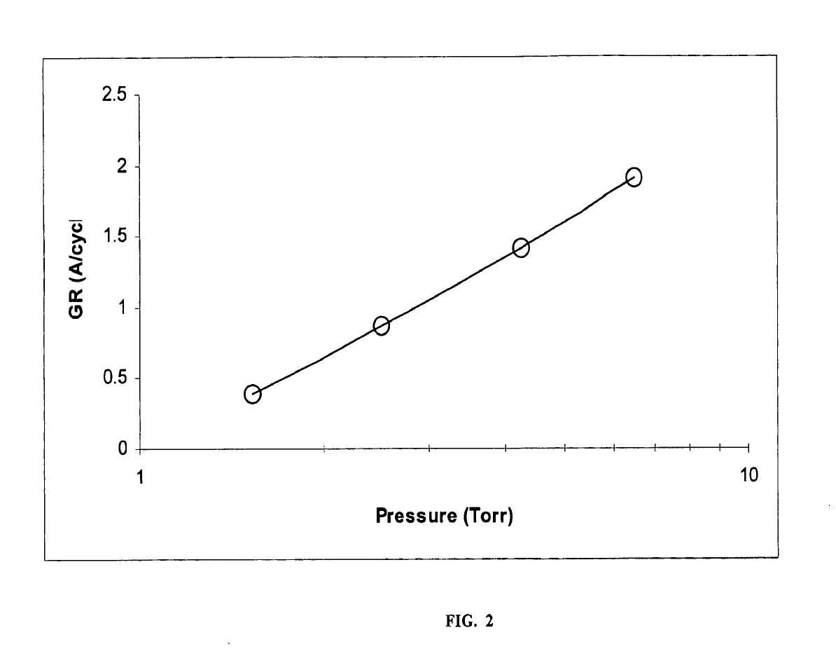

FIG. 2 is a graph plotting ALD growth rates at different deposition pressures when precursor concentration, delivery flow rate, and deposition temperature are held constant. In particular, for the plot shown in FIG. 2, precursor concentration was set at 0.15M, delivery flow rate was set at 2 uL/min, and deposition temperature was set at 230° C. It can be seen in FIG. 2 that changes to the pressure result in significant changes to the thin film growth rate.

It is believed that the advantages of the present invention are provided at least in part because within certain ranges, the solvent partial pressure in the deposition chamber forms a temporary surface layer that does not react with surface reactive sites chemically. The solvent also acts to carry the precursor to the surface and helps remove ligand fragments from the deposition surface, thus opening up free reaction sites for more complete saturation and reaction with the precursor molecules. The total pressure in the deposition chamber can be varied from 0.1 to 50 Torr. The preferred deposition pressure is between 1 and 15 Torr.

It is anticipated that other embodiments and variations of the present invention will become readily apparent to the skilled artisan in the light of the foregoing description, and it is intended that such embodiments and variations likewise be included within the scope of the invention as set out in the appended claims.

1. A method of atomic layer deposition comprising:
deliver a precursor solution, comprising a metal precursor and solvent combination at a predetermined concentration, to a vaporizer at a fixed flow rate;
vaporize the precursor solution;
deliver the vaporized precursor solution to a deposition chamber at a predetermined temperature and pressure for a predetermined length of time;
purge the deposition chamber with inert gas for a predetermined length of time;
deliver a second precursor to the deposition chamber for a predetermined length of time;
purge the deposition chamber with inert gas for a predetermined length of time;
repeat delivery of precursors and purge until a desired thin film thickness is achieved.

2. The method of claim 1 wherein the metal precursor is selected from Hf[N(EtMe)]₄, Hf(NO₃)₄, HfI₄, [(t-Bu)Cp]₂HfMe₂, Hf(O₂C₅H₁₁)₄, Cp₂HfCl₂, Hf(OC₄H₉)₄, Hf(OC₂H₅)₄, Al(OC₃H₇)₃, Pb(OC(CH₃)₃)₂, Zr(OC(CH₃)₃)₄, Ti(OCH(CH₃)₂)₄, Ba(OC₃H₇)₂, Sr(OC₃H₇)₂, Ba(C₅Me₅)₂, Sr(C₅i-Pr₃H₂)₂, Ti(C₅Me₅)(Me₃), Ba(thd)₂*triglyme, Sr(thd)₂*triglyme, Ti(thd)₃, RuCp₂, Ta(NMe₂)₅ or Ta(NMe₂)₃(NC₉H₁₁) and the solvent is selected from dioxane, toluene, n-butyl acetate, octane, ethylcyclohexane, 2-methoxyethyl acetate, cyclohexanone, propylcyclohexane, 2-methoxyethyl ether (diglyme), butylcyclohexane or 2,5-dimethyloxytetrahydrofuran.

3. The method of claim 1 wherein the predetermined concentration is 0.01-10 Molar.

4. The method of claim 1 wherein the fixed flow rate is 0.01-10000 uL/min liquid.

5. The method of claim 1 wherein the predetermined temperature is 100-600° C.

6. The method of claim 1 wherein the predetermined pressure is 0.1-10 Torr.

7. A method of atomic layer deposition comprising:
deliver a precursor solution, comprising a metal precursor and solvent combination at a predetermined concentration, to a vaporizer at a fixed flow rate;
vaporize the precursor solution;
deliver the vaporized precursor solution to a deposition chamber at a predetermined temperature for a predetermined length of time;
alter the pressure of the deposition chamber during delivery of the vaporized precursor solution;
purge the deposition chamber with inert gas for a predetermined length of time,
deliver a second precursor to the deposition chamber for a predetermined length of time;
purge the deposition chamber with inert gas for a predetermined length of time;
repeat delivery of precursors and purge until a desired thin film thickness is achieved.

8. The method of claim 7 wherein the pressure of the deposition chamber is increased.

9. The method of claim 7 wherein the pressure of the deposition chamber is decreased.

10. The method of claim 7 wherein the pressure of the deposition chamber varies between 0.1 to 50 Torr.

11. The method of claim 10 wherein the pressure of the deposition chamber varies between 1 and 15 Torr.

12. A thin film layer deposited by atomic layer deposition wherein the deposition comprises:
delivering a precursor solution, comprising a metal precursor and solvent combination at a predetermined concentration, to a vaporizer at a fixed flow rate;
vaporizing the precursor solution;
delivering the vaporized precursor solution to a deposition chamber at a predetermined temperature and pressure for a predetermined length of time; purging the deposition chamber with inert gas for a predetermined length of time;
delivering a second precursor to the deposition chamber for a predetermined length of time;
purging the deposition chamber with inert gas for a predetermined length of time; and
repeating delivery of precursors and purge until the thin film layer is deposited.

13. The thin film of claim 12 wherein the metal precursor is selected from Hf[N(EtMe)]₄, Hf(NO₃)₄, HfI₄, [(t-Bu)Cp]₂HfMe₂, Hf(O₂C₅H₁₁)₄, Cp₂HfCl₂, Hf(OC₄H₉)₄, Hf(OC₂H₅)₄, Al(OC₃H₇)₃, Pb(OC(CH₃)₃)₂, Zr(OC(CH₃)₃)₄, Ti(OCH(C₁H₃)₂)₄, Ba(OC₃H₇)₂, Sr(OC₃H₇)₂, Ba(C₅Me₅)₂, Sr(C₅i-Pr₃H₂)₂, Ti(C₅Me₅)(Me₃), Ba(thd)₂*triglyme, Sr(thd)₂*, triglyme, Ti(thd)₃, RuCp₂, Ta(NMe₂)₅ or Ta(NMe₂)₃(NC₉H₁₁) and the solvent is selected from dioxane, toluene, n-butyl acetate, octane, ethylcyclohexane, 2-methoxyethyl acetate, cyclohexanone, propylcyclohexane, 2-methoxyethyl ether (diglyme), butylcyclohexane or 2,5-dimethyloxytetrahydrofuran.

14. A thin film deposited by atomic layer deposition wherein the deposition comprises:
delivering a precursor solution, comprising a metal precursor and solvent combination at a predetermined concentration, to a vaporizer at a fixed flow rate;
vaporizing the precursor solution;
delivering the vaporized precursor solution to a deposition chamber at a predetermined temperature for a predetermined length of time;
altering the pressure of the deposition chamber during delivery of the vaporized precursor solution;
purging the deposition chamber with inert gas for a predetermined length of time;
delivering a second precursor to the deposition chamber for a predetermined length of time;
purging the deposition chamber with inert gas for a predetermined length of time;
repeating delivery of precursors and purge until the thin film is deposited.

15. The thin film of claim 14 wherein the metal precursor is selected from Hf[N(EtMe)]₄, Hf(NO₃)₄, HfI₄, [(t-Bu)Cp]₂HfMe₂, Hf(O₂C₅H₁₁)₄, Cp₂HfCl₂, Hf(OC₄H₉)₄, Hf(OC₂H₅)₄, Al(OC₃H₇)₃, Pb(OC(CH₃)₃)₂, Zr(OC(CH₃)₃)₄, Ti(OCH(CH₃)₂)₄, Ba(OC₃H₇)₂, Sr(OC₃H₇)₂, Ba(C₅Me₅)₂, Sr(C₅i-Pr₃H₂)₂, Ti(C₅Me₅)(Me₃), Ba(thd)₂*triglyme, Sr(thd)₂*, triglyme, Ti(thd)₃, RuCp₂, Ta(NMe₂)₅ or Ta(NMe₂)₃NC₉H₁) and the solvent is selected from dioxane, toluene, n-butyl acetate, octane, ethylcyclohexane, 2-methoxyethyl acetate, cyclohexanone, propylcyclohexane, 2-methoxyethyl ether (diglyme), butylcyclohexane or 2,5-dimethyloxytetrahydrofuran.
